(19) United States
(12) Patent Application Publication
(10) Pub. No.: US 2011/0014731 A1
(43) Pub. Date: Jan. 20, 2011

(54) METHOD FOR SEALING A PHOTONIC DEVICE

(76) Inventors: Kelvin Nguyen, Corning, NY (US); Lu Zhang, Painted Post, NY (US)

Correspondence Address: CORNING INCORPORATED, SP-TI-3-1, CORNING, NY, 14831, US

(21) Appl. No.: 12/503,547

(22) Filed: Jul. 15, 2009

(51) Int. Cl. H01L 21/50; H01L 31/18

(52) U.S. Cl. 438/26; 438/64; 156/272.8; 257/E21.499; 257/E33.056

(57) ABSTRACT

Methods for sealing a photonic device are disclosed. The photonic device may, for example, comprise a display device, a lighting device or a photovoltaic device. The device is sealed with a glass frit that is heated with a laser from both sides of the device (through both glass substrate plates), either sequentially or simultaneously. The methods can facilitate wider seal widths, and wider overall frit wall widths for increased device strength.

### TECHNICAL FIELD

This invention is directed to a method of sealing a photonic device, and in particular, forming a glass package comprising glass plates hermetically sealed with a glass-based frit.

### BACKGROUND

Organic light emitting diode (OLED) devices are an emerging technology for display applications, and are only now advancing to dimensions exceeding those found in such common devices as cell phones. As such, they are still expensive to produce.

One difficulty associated with OLED devices, such as OLED-based displays, is the need to maintain an hermetically sealed environment for the organic light emitting materials used for the OLEDs. This arises because the organic materials quickly degrade in the presence of even minute amounts of oxygen or moisture. To that end, a glass seal may be provided by a glass-based frit material that seals two glass plates together, provides sufficient hermeticity to the organic materials contained within the resulting package. Such glass packages have proven to be far superior to adhesive-sealed devices. In a typical frit sealed configuration, the glass-based frit is deposited on a first glass plate, referred to as the cover plate, in the form of a closed loop. The frit is deposited as a paste that is subsequently heated in a furnace for a period of time and at a temperature sufficient to at least partially sinter (pre-sinter) the frit in place on the cover plate, making later assembly of the display easier. The OLED is then deposited on a second glass plate, generally referred to as the backplane plate or simply backplane. The OLED may contain, for example, electrode materials, organic light emitting materials, hole injection layers, and other constituent parts as necessary. The two plates are then brought into alignment and the pre-sintered frit is heated with a laser that softens the frit and forms an hermetic seal between the two glass plates.

As display devices increase in size, demands on the seal integrity and robustness also increase. It has been found that one reason that frit-based seals may fail is because of incomplete utilization of the available frit surface. That is, the width of the frit that actually seals to the substrate glass is not as wide as would be possible if the entire available width were sealed.

### SUMMARY

In one embodiment, a method of forming a photonic device is disclosed comprising positioning a first glass plate comprising a loop of glass based frit forming a wall over a second glass plate comprising an organic photonically active material disposed thereon, irradiating a first surface of the wall with a first laser beam through the first glass plate, the first wall surface opposing the first glass plate, irradiating a second surface of the wall with a second laser beam through the second glass plate, the second wall surface opposing the second glass plate and wherein the irradiating the first and second surfaces of the wall couples the first glass plate to the second glass plate, and wherein the second surface comprises a sealed portion and an unsealed portion. This can be determined by viewing through one of the substrate glass plates, such as with a microscope. A width of the sealed portion preferably comprises equal to or greater than 80% of the maximum width of the wall. Preferably, the width of the sealed portion is between 80% and 98% of the maximum width of the wall. The sealing of the first surface of the frit wall and the second surface of the frit wall with the first and second laser beams, respectively, can be performed sequentially or simultaneously. If performed sequentially, the first and second laser beams can be the same laser beam, and the sealing accomplished by reorienting the laser (and thus the laser beam), or by reorienting (e.g. flipping) the assembly to be sealed.

In some embodiments, the assembly to be sealed may be heated prior to the irradiating and sealing to reduce stress in the glass plates of the assembly to be sealed. The assembly may be heated, for example, by supporting the assembly on a hot plate.

When viewed from a side of the assembly, that is when viewed through the glass substrate plate to which the frit was not first pre-sintered to, the unsealed portion comprises a pair of unsealed portions positioned on opposite sides of the sealed portion. The width of the sealed portion is measured and the maximum width of the frit wall is measured (e.g. from the outside of one unsealed portion to the outside of the other unsealed portion), and the sealed portion is divided by the maximum width to obtain the seal width. The seal width can be expressed as a percentage.

The organic material disposed between the two plates may be, for example, an electroluminescent organic material. For example, the organic material may comprise an organic light emitting diode and further comprise a display or lighting panel, or it may comprise a photovoltaic device.

In another embodiment, a method of sealing a glass package is described comprising positioning a first glass plate over a second glass plate, the first glass plate comprising a wall adhered to a surface thereof, the wall comprising a glass sealing material, irradiating a first surface of the wall with a first laser beam through the first glass plate, the first wall surface adjacent the first glass plate, irradiating a second surface of the wall with a second laser beam through the second glass plate, the second wall surface adjacent the second glass plate and wherein the irradiating the first and second surfaces of the wall couples the first glass plate to the second glass plate, and wherein the second surface comprises a sealed portion and an unsealed portion, and wherein a width of the sealed portion comprises equal to or greater than 80% of the maximum width of the wall.

In one embodiment, the method comprises irradiating the first and second surfaces sequentially. In another embodiment, the first and second surfaces may be irradiated simultaneously.

The invention will be understood more easily and other objects, characteristics, details and advantages thereof will become more clearly apparent in the course of the following explanatory description, which is given, without in any way implying a limitation, with reference to the attached Figures. It is intended that all such additional systems, methods, features and advantages be included within this description, be within the scope of the present invention, and be protected by the accompanying claims.

### BRIEF DESCRIPTION OF THE DRAWINGS

FIG. 1 is a cross sectional side view of an exemplary photonic device (e.g. an organic light emitting diode assembly or device) according to embodiments of the present invention.

FIG. 2 is a perspective view of a cover glass plate comprising the assembly of FIG. 1 and having a glass frit wall disposed thereon.

FIG. 3 is a perspective view of a backplane plate comprising the assembly of FIG. 1 and having an electroluminescent device disposed thereon.

FIG. 4 is a cross sectional side view of the photonic device of FIG. 1 being sealed from a first side.

FIG. 5 is a cross sectional side view of the photonic device of FIG. 1 being sealed from two sides.

FIG. 6 is a close up view of a cross section of a frit wall disposed between the cover glass plate and the backplane glass plate showing various dimension of the frit wall.

FIG. 7 is a top down view of a portion of the frit wall after sealing the wall, and illustrating the two dimensional appearance of the sealed and unsealed portions, and the various measurements to obtain a seal width.

FIG. 8 is a plot of strength vs. failure probability of a sealed device tested in anticlastic bending and sealed from both sides for two different maximum frit wall widths, and showing that the larger the wall width, and the seal width, the greater the seal strength.

FIG. 9 is a plot of strength vs. failure probability of a sealed device tested in four point bending and sealed from both sides for two different maximum frit wall widths, and showing that the larger the wall width, and the seal width, the greater the seal strength.

### DETAILED DESCRIPTION

In the following detailed description, for purposes of explanation and not limitation, example embodiments disclosing specific details are set forth to provide a thorough understanding of the present invention. However, it will be apparent to one having ordinary skill in the art, having had the benefit of the present disclosure, that the present invention may be practiced in other embodiments that depart from the specific details disclosed herein. Moreover, descriptions of well-known devices, methods and materials may be omitted so as not to obscure the description of the present invention. Finally, wherever applicable, like reference numerals refer to like elements.

As used herein a frit is defined as a glass-based material comprising an inorganic glass powder. The glass-based frit, or simply “frit”, may optionally include one or more volatile binders and/or a solvent as a vehicle. The frit may, if desired, further include an inert, usually crystalline, material that serves to modify a coefficient of thermal expansion (CTE) of the frit to improve matching the frit CTE to the CTE of the glass substrate plates being joined. Thus, while the frit is primarily composed of a glass, it may also include other inorganic and organic materials. The frit may exist in various forms. For example, when the glass powder is mixed with binders and a vehicle, the frit may form a paste. Heating of the frit at a temperature sufficient to drive off (evaporate) the volatile binders and vehicle but not sinter the frit may form a glass powder cake, wherein the glass powder is lightly bonded in a specific shape, but wherein the glass particles have not flowed significantly. Heating at a higher temperature can cause the glass particles to flow and coalesce, thereby at least partially sintering (“pre-sintering”) the frit. Additional heating at a high temperature above the melting temperature of the frit glass can result in a complete coalescing of the glass particles, wherein the granular nature of the glass particles disappears, although any crystalline CTE-modifying constituents disposed in the frit may remain within the glass matrix.

As used herein, the term “frit glass” will be used to refer to the glass portion of the frit, excluding the vehicle, binders or CTE-modifying constituents.

As used herein, a photonic device is represented by a device that either employs light to generate a current or voltage, or the application of a voltage or current to generate light. Non-limiting examples of photonic devices include light emitting diode (LED) displays such as organic light emitting diode (OLED) displays, photovoltaic devices (solar cells), lighting panels, including organic light emitting diode lighting panels, and so forth. While a broad range of applications can benefit from the present invention, it is particularly effective in preventing the degradation of organic materials that may be used in some of the foregoing devices, such as those employing organic light emitting diodes. For that reason, the following description will be discussed in terms of organic light emitting diode devices, with the understanding that the teachings presented herein can be applied to other photonic devices.

In a typical method for forming a photonic device, such as an organic light emitting diode (OLED) display (e.g. television, computer monitor) or a lighting device, an electroluminescent device is sealed between two plates of glass with a frit sealing material. This is particularly effective for the sealing of electroluminescent devices comprising an organic material because most organic materials are incapable of exposure to oxygen or moisture for any appreciable time without serious degradation. The seal is therefore preferably hermetic. To that end, the sealing material may be a glass-based frit that is positioned between the two glass plates and heated.

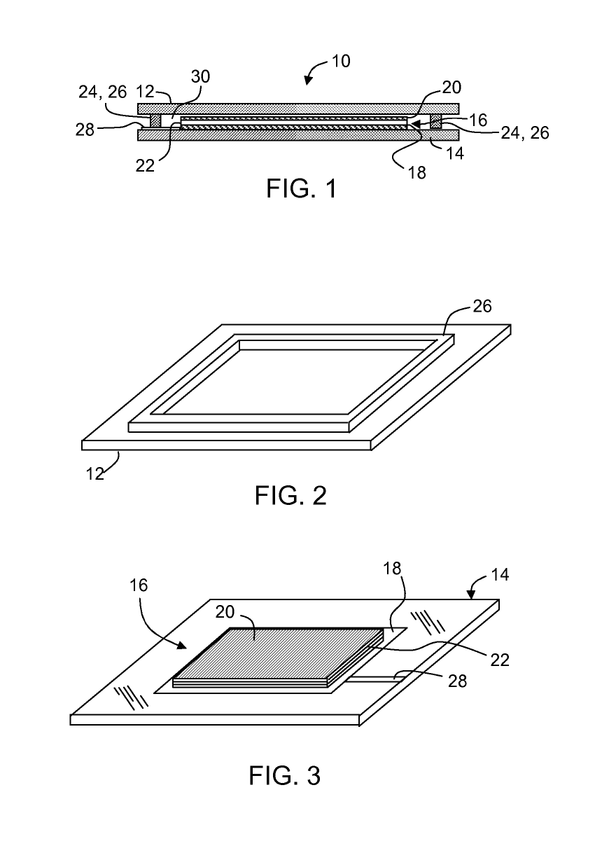

FIG. 1 depicts an exemplary organic light emitting diode device 10 comprising first glass plate 12 (cover plate 12), second glass plate 14 (backplane plate 14), and an electroluminescent device 16. Electroluminescent device 16 may comprise, for example, a first electrode material 18 (e.g. anode), second electrode material 20 (e.g. cathode) and one or more layers of an organic electroluminescent material 22 (e.g. organic light emitting material) disposed between the first and second electrode materials. Sealing material 24 forms a hermetic seal between the first and second glass plates.

In a conventional sealing operation for photonic devices, such as organic light emitting diode devices, a glass-based frit is employed as sealing material 24 and is deposited onto first (cover glass) plate 12 and pre-sintered in place by heating the cover glass—frit assembly in a furnace for a time and at a temperature sufficient to both drive off any organic materials in the frit and to sinter and adhere the frit 24 onto the glass plate. A cover plate comprising a pre-sintered frit wall 26 in the shape of a frame or loop is illustrated in FIG. 2

The second glass plate, shown in FIG. 3, comprises one or more layers of an electroluminescent material 22 deposited thereon. The second glass plate may further include other layers, such as anode 18, cathode 20, and at least one electrically conducting lead 28. Electrically conducting lead 28 may be a metal or a metal oxide.

Once frit 24 has been pre-sintered and adhered to cover plate 12 to form frit wall 26, cover plate 12 and backplane plate 14 comprising organic electroluminescent device 16 are aligned, preferably in an inert atmosphere (such as in a suitably sized glove box containing a controlled atmosphere) so that when the two plates are brought together, the organic electroluminescent device is encased by cover plate 12, backplane plate 14 and frit wall 26. That is, the backplane, the cover plate and the frit wall form cavity 30 containing the organic material. Frit wall 26 can then be re-heated to soften the wall so that the wall adheres both to the cover plate and the backplane plate. When the glass-based frit wall cools, it forms an hermetic seal between the two glass plates that protects the organic material from oxygen and moisture.

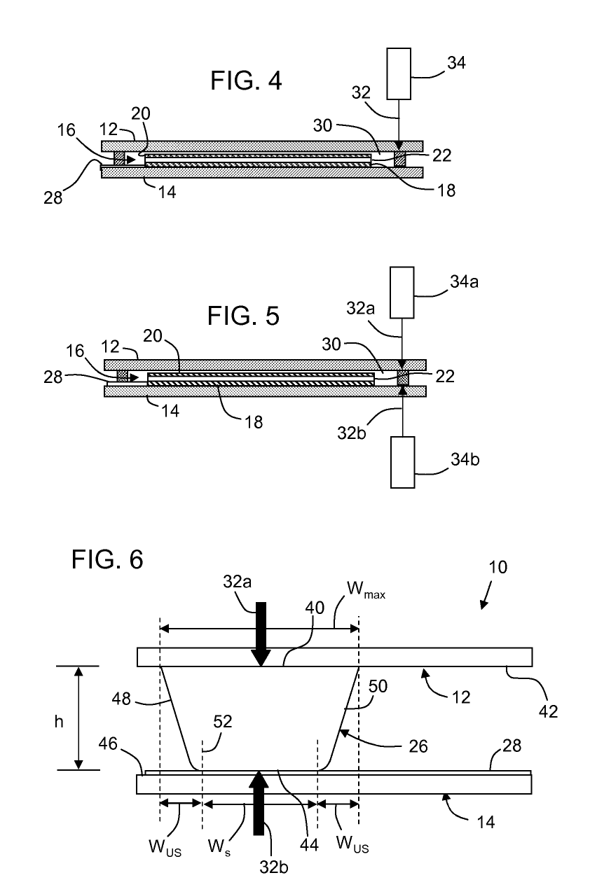

One method of hermetically sealing the cover and backplane substrates is by irradiating frit wall 26 positioned between glass plates 12 and 14 through cover plate 12 with a laser beam 32 emitted by sealing laser 34 as depicted in FIG. 4. Preferably, the glass of the cover plate (or the plate through which the laser beam is transmitted) does not absorb significant light at the wavelength or range of wavelengths over which the glass-based frit absorbs the light so that sealing laser beam 32 passes through the glass plate substantially un-attenuated. This prevents heating of the plates that might interfere with the heating of the frit, or might damage the organic materials. In other words, it is preferred that cover plate 12 and backplane plate 14 are transparent, or nearly so, at the wavelength or wavelengths output by the sealing laser 34 so that heating of the cover plate does not result in the organic material exceeding a temperature of about 125° C., and preferably does not exceed a temperature greater than 100° C. Beam 32 produced by sealing laser 34 is traversed over the frit to soften the frit and adhere it to both the cover and backplane glass plates, thereby forming the hermetic seal between them. Also, irradiating the frit through the cover glass plate avoids the need to seal through the one or more electrical leads 28 connecting the anode and cathode electrodes to components outside the seal area. In other words, by irradiating through glass cover plate 12, a clear path for the laser beam is provided to the frit without significant attenuation.

As mentioned above, it is desirable that the glass plate through which the laser beam passes is largely transparent to the laser beam. This prevents heating of the glass plate that may significantly increase the temperature of the organic material. On the other hand, the frit must be highly absorbing to the laser beam so that sufficient energy is absorbed to heat and soften the frit. In fact, most of the energy of the laser beam is absorbed at or near the surface of the frit (e.g. the frit-cover plate interface), typically within several microns of the surface. Thus, heating below the surface of the frit is primarily by thermal conduction.

During the pre-sintering step, the individual particles comprising the frit flow and begin to coalesce (i.e. consolidate). At the completion of the pre-sintering step, the frit is well-adhered to the cover plate, but may not be fully consolidated throughout the bulk of the frit. Thus, during the laser sealing portion of the process, sufficient heating is required so that not only does the frit adhere to the backplane to seal the cover plate to the backplane, but that the frit glass also substantially consolidates. Incomplete consolidation can lead to voids in the frit wall, or un-adhered interfaces between the frit wall and the underlying surface (e.g. glass substrate surface, lead, etc.).

In addition to hermeticity, it is also desirable that the seal have sufficient strength to ensure the integrity of the seal during normal handling or use. This is particularly important, for example, when the dimensions of the completed article, e.g. display, are large and the stresses on the seal similarly large. To this end, the portion of the frit actually adhered to the underlying surface should be as wide as possible. Typically, the intensity of the laser used to perform the sealing has a Gaussian profile, so more energy is conveyed to the center of the frit than to the edges. While every effort is employed to establish a consistent intensity across the width of the frit, such as increasing the width of the beam to ensure that only the central portion of the beam overlaps the frit, this has proven to be only partially successful. First, to capitalize on the surface area of the backplane plate available for deposition of the electroluminescent device, display manufacturers typically extend the electroluminescent device as close to the frit as possible, so laser beam size is necessarily constrained.

Moreover, it should also be recognized that regardless of the manner of depositing the frit on the cover plate prior to the pre-sintering step (e.g. dispensing through a nozzle, screen printing, etc.), it is difficult to obtain abrupt (e.g. square) corners on the open face of the frit. This, in addition to surface tension effects during the pre-sintering process, can lead to rounded corners that can impede the frit from sealing fully across the width of the frit, particularly proximate the backplane glass plate.

Finally, as described above, the backplane plate usually includes at least one electrically conductive lead 28 deposited on the inside surface of the backplane that forms an electrical path between the electroluminescent device and elements outside cavity 30. Because the thermal properties of the one or more electrical leads differ from the thermal properties of the backplane glass or the glass-based frit, the sealing width over an electrical lead area may differ from the sealing area over the electrical lead-free glass areas. In fact, in some instances the seal width can be greater over the lead area than over the lead-free glass area because the electrical leads can conduct heat better than the backplane glass, and therefore even out the temperature across the width of the frit wall at the frit—backplane interface. As used herein, seal width refers to the width of the portion of frit wall 26 that is sealed to the backplane (or more appropriately, the plate to which the frit was not first pre-sintered to) divided by the maximum width of the frit wall. The seal width may be expressed as a percentage by multiplying the quotient above by 100%.

One attempting to seal a photonic device such as an OLED display device is thus faced with competing needs. The glass package should be sealed as quickly as possible to maximize manufacturing throughput, but not so fast that there is insufficient time for the necessary heat conduction through the thickness of the frit. The laser beam should be wide enough that the flattest portion of the beam covers the width of the frit, but not so wide that the beam irradiates the electroluminescent device contained within the package. This is particularly true if the electroluminescent device comprises an organic electroluminescent material, such as used in an organic light emitting diode (OLED) device. The laser beam power should be high enough that enough optical energy is imparted to the frit to cause the frit to heat and soften for a given traverse rate of the beam over the frit, but not so high that the high absorbance and poor thermal conduction of the glass-based frit causes overheating of the irradiated surface of the frit. Moreover, the seal width should be as wide and consistent as possible to improve seal strength, particularly for large displays.

Accordingly, a method is disclosed herein where seal widths in excess of 80% can be obtained, preferably at least between about 80% and 95%. Such seal widths are larger than the seal widths of about 70%-78% that are obtained when sealing from only a single side. FIG. 5 shows photonic assembly 10 comprising first glass plate 12, second glass plate 14, first electrode 18, second electrode 20, electroluminescent layer 16 disposed between the first and second electrodes, and an electrical lead 28 disposed on second glass plate 14 and connected to one of the electrodes.

First glass plate 12 comprises a loop of glass-based frit 24 that forms a wall 26 on the first glass plate. Frit 24 may be, for example, a low temperature glass frit that has a substantial optical absorption cross-section at a predetermined wavelength that matches or substantially matches the operating wavelength of the laser used in the sealing process. The frit may contain, for example, one or more light absorbing ions chosen from the group including iron, copper, vanadium, neodymium and combinations thereof. The frit may also include a filler (e.g., an inversion filler or an additive filler) that changes the coefficient of thermal expansion of the frit so that it matches or substantially matches the coefficient of thermal expansions of glass plates 12 and 14. The cross sectional shape of the wall is not particularly limited, and may be, for example, substantially rectangular or trapezoidal. An exemplary frit wall forming an hermetic seal between first and second glass plates 12 and 14 in accordance with embodiments of the present invention is shown in the cross sectional illustration of FIG. 6. The frit wall comprises a first wall surface 40 adjacent surface 42 of first glass plate 12, and an opposite second surface 44. Second surface 44 may be in contact with surface 46 of second glass plate 14, or second surface 44 may be in contact with one or more other materials disposed on second glass plate 14. These additional layers may comprise one or more electrode layers such as cathode metal-leads, indium tin oxide (ITO) and other protective materials barrier layers or an electrical lead (such as lead 28 as illustrated in FIG. 6). Each material on the device substrate (i.e. substrate plate 14) has different thermal properties (e.g., coefficient of thermal expansion (CTE), heat capacity and thermal conductivity). The various thermal properties on the device side can cause a significant variation of the bonding strength between the frit and the device boundary after completing the laser sealing process. Frit wall 26 also comprises outer side surface 48, an inner side surface 50, a maximum width Wₘₐₓ, height (thickness) h and seal width Wₛ.

Frit wall 26 may be pre-sintered prior to sealing first substrate 12 to second substrate 14. To accomplish the pre-sintering, frit 24 is heated so that wall 26 becomes attached to first substrate 12. Then, first substrate 12 with frit 24 deposited thereon can be placed in a furnace that “fires” or consolidates frit 24 at a temperature that depends on the composition of the frit to form wall 26. During the pre-sintering phase, frit 24 is heated and organic binder materials contained within the frit are burned out.

The thickness, or height h, of wall 26 is preferably on the order of between 5 and 30 microns, preferably between about 10 and 20 microns, and more preferably between about 12 and 15 microns, depending on the application for a particular device (e.g. display device). An adequate but not overly thick wall allows the substrate plates to be sealed from the backside of first substrate 12. If wall 26 is too thin there may be insufficient heating. If the wall 26 is too thick it will be able to absorb enough energy at first surface 40 to melt, but will prevent the energy needed to melt the frit from reaching the region of the wall proximate second substrate 14. First glass plate 12 is positioned relative to second glass plate 14 so that wall 26 is positioned between the glass plates and circumscribing organic light emitting material 22.

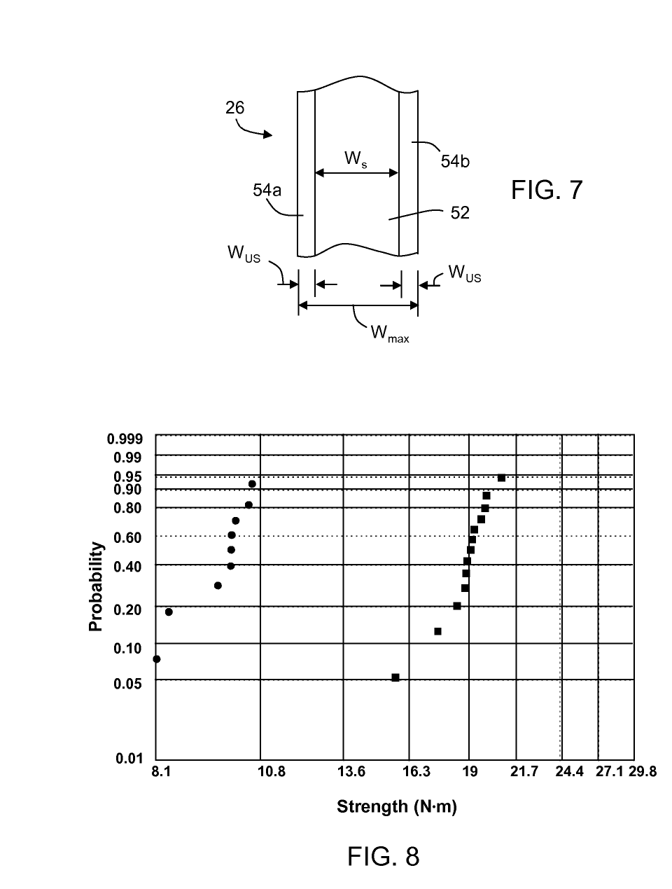

Referring briefly to FIG. 4, during a sealing process where only a single laser beam traverses the frit wall, and particularly, when only a single laser beam traverses surface 40, a portion of wall surface 44 may seal to the adjacent underlying material (e.g. substrate plate 14). However, typically, a portion of wall surface 44 does not adhere to the adjacent material. As noted, heat is transferred to second surface 44 largely via conduction from wall surface 40, and the residence time and/or power of the beam may be insufficient to promote thorough melting of the frit wall through a thickness of the wall. Thus, although an hermetic seal may be formed by virtue of there being at least a minimal adhesion around the perimeter of the wall at both surfaces 40 and 44, the seal may lack mechanical strength, particularly, for example, at the interface between frit wall surface 44 and the underlying material (e.g. glass plate 14), and be easily broken. The degree of sealing can be characterized by a seal width. The seal width is calculated by the width of the sealed portion of the frit surface (Wₛ) divided by the maximum width of the frit wall (Wₘₐₓ). This can best be seen with the aid of FIGS. 6 and 7.

FIG. 7 shows a view of frit wall 26 from the direction of laser beam 32b as depicted in FIG. 6. FIG. 7 shows a sealed portion 52 of frit wall 26 flanked by two unsealed portions 54a and 54b. Unsealed portions 54a and 54b have a width in the current view of W_{US}. The unsealed width of unsealed portion 54a may be the same or different than the unsealed width of portion 54b. It should be noted that although the structure being observed is three dimensional, the view (such as through a microscope) is 2 dimensional, and thus the measurements of the relative widths of the various portions can be easily measured as though laid on a two dimensional plane.

As noted, this seal width metric can easily be expressed as a percentage my multiplying the previous quotient by 100%. Thus, by way of example, for a frit wall having a maximum width Wₘₐₓ of 2 mm, and wherein a surface of the frit wall (either the first or second surfaces 40 or 44) is adhered across only 1 mm of the maximum frit width, the seal width for that surface is 50%. As the seal width between surface 42 of first substrate plate 12 and first surface 44 of frit wall 26 is typically of a very high percentage due to the pre-sintering step, unless otherwise indicated herein, seal width will be used to denote the degree of sealing of the surface of the frit that is not adhered during pre-sintering. This is typically second surface 44 sealed to second glass plate 14 (backplane 14).

It has been shown that the larger the seal width, the greater the mechanical strength of the frit wall. FIG. 8 shows a Weibull plot of the anticlastic bending strength (force in Newton·meters vs. failure probability) of two samples having maximum frit widths of 0.4 mm (circles to the left) and a 0.7 mm frit wall width (squares to the right). The seal was formed by sealing first one side of the sample and then the other side (by flipping the assembly). It sealed at a speed of 10 mm/s at a laser power of 24 watts. The seal width of the 0.4 mm sample was 79%±1% and the seal width of the 0.7 mm sample was 85%±1%. The circle data (0.4 mm sample) comprises a Weibull slope m of 11.3 and a Weibull characteristic stress So of 10.2 Newton·meters and the square data (0.7 mm sample) comprises an m value of 15.2 and an So value of 19.5 Newton·meters. The seal width of the 0.7 mm frit wall was about 88% wider than the seal width of the 0.4 mm frit wall. The data show an approximately 2× increase in anticlastic seal strength for the wall having the larger seal width.

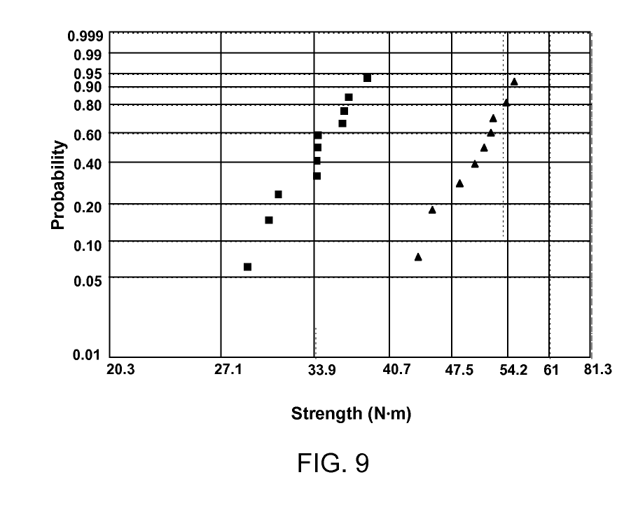

FIG. 9 shows similar Weibull data for a 0.4 mm wall width and a 0.7 mm wall width tested in four point bending. The sealing parameters were the same as in the preceding example. The Weibull slope m for the 0.4 mm sample was 11.9 and the characteristic stress So was 35.4 Newton·meters. The Weibull slope m for the 0.7 mm sample was 13.3 and the characteristic strength So was 52.6 Newton·meters. In this instance the seal width for the 0.7 mm wall width was 80%±1% and the seal width for the 0.7 mm sample was 84%±1%, approximately 84% larger than the 0.4 mm wall width. The seal strength of the 0.7 mm wall (triangles to the right) was 49% larger than the seal strength of the 0.4 mm wall (squares to the left).

In accordance with one embodiment, a method of sealing a photonic device comprises dispensing a glass-based frit on cover glass plate 12 and pre-sintering the frit to form a wall on the cover plate. The glass-based frit may be pre-sintered, for example, by heating the cover plate and the frit in an oven or furnace. An exemplary heating schedule can be, for example, 400° C. for at least 15 minutes.

In a following step, laser beam 32a irradiates first surface 40 of frit wall 26 through first glass plate 12. Relative motion between beam 32a and frit wall 26 causes first surface 40 of frit wall 26 to heat and soften. Wall 26 subsequently cools and solidifies. Second laser beam 32b similarly irradiates second surface 44 of frit wall 26 through second glass plate 14, and in some instances through an electrode (e.g. anode 18) or other layer disposed on plate 14. Relative motion between laser beam 32b and frit wall 26 causes beam 32b to heat and soften the wall. Wall 26 subsequently cools and solidifies, hermetically sealing electroluminescent layer 16 between first and second glass plates 12 and 14, respectively. Second surface 44 can be heated subsequent to the heating of first surface 40, or simultaneously with the heating of first surface 40. For example, in one embodiment, first surface 40 of frit wall 26 can be heated by laser beam 32. The assembly to be sealed can then be flipped and laser beam 32 used to similarly heat surface 44, completing the seal. Alternatively, a first laser 34a can be used to heat first surface 40 with a first laser beam 32a, and a second laser 34b can heat the second surface 44 with a second laser beam 32b. In another embodiment, two beams may be derived from a single laser by splitting one beam coming from the laser into two beams. Preferably, the seal width resulting from two-sided sealing is greater than about 80%, more preferably the seal width is greater than about 85%, more preferably greater than about 90%. A typical range for seal width is between 80% and 95%, but can be greater than 95%.

To improve seal strength, one or both of the glass plates 12 and/or 14 maybe heated prior to irradiating frit wall 26 to reduce stresses that may be present while forming the seal. For example, a heated support (“hot plate” may be used to support the assembly before the irradiating in order to raise the temperature of one of the substrate plates. The heated substrate plate, or plates, should be maintained at a temperature below 125° C., preferably less than 100° C. to ensure the organic electroluminescent material is not damaged, although the sealing of a glass package that does not contain organic materials is not bound by this restriction.

In some embodiments, a microwave generator may be substituted for laser 34a and/or laser 34b, where the frit wall is heated by microwave beams rather than laser beams.

As noted above, two-sided sealing can be used to increase the width, and thus the seal strength, of a given seal without damage to the frit. Ordinarily, as the overall width of the frit wall increases, the mass of the frit increases, requiring more energy to accomplish the sealing. The energy needed to effectively seal a device can be high enough to damage the frit—essentially burning the frit. Two-sided sealing provides a method of applying the needed energy without unduly increasing the energy applied at a single point, as would be the case with one-sided sealing.

It has been found that single-sided sealing typically results not only in relatively low seal width, but also that small areas across the seal width are also not adhered to the underlying material (e.g. glass, electrode, lead, etc.). The result is small pockets of unsealed frit that appears a small “speckles” along the seal surface. Thus, even though a conventional single-sided seal may exhibit an overall seal width of, say, 70%, the effective seal width that accounts for these very small unsealed regions can be lower, further weakening the seal. Two sided sealing significantly reduces not only the speckling that appears at the seal interface, but can also reduce the formation of small voids within the body of the frit wall.

It should be emphasized that the above-described embodiments of the present invention, particularly any “preferred” embodiments, are merely possible examples of implementations, merely set forth for a clear understanding of the principles of the invention. Many variations and modifications may be made to the above-described embodiments of the invention without departing substantially from the spirit and principles of the invention. All such modifications and variations are intended to be included herein within the scope of this disclosure and the present invention and protected by the following claims.

What is claimed is:

1. A method of forming a photonic device comprising:
positioning a first glass plate comprising a loop of glass based frit forming a wall over a second glass plate comprising an organic photonically active material disposed thereon;
irradiating a first surface of the wall with a first laser beam through the first glass plate, the first wall surface opposing the first glass plate;
irradiating a second surface of the wall with a second laser beam through the second glass plate, the second wall surface opposing the second glass plate; and
wherein the irradiating the first and second surfaces of the wall couples the first glass plate to the second glass plate, and wherein the second surface comprises a sealed portion and an unsealed portion, and wherein a width of the sealed portion comprises equal to or greater than 80% of the maximum width of the wall.

2. The method according to claim 1, wherein the width of the sealed portion is between 80% and 98% of the maximum width of the wall.

3. The method according to claim 2, wherein irradiating the first surface of the wall and irradiating the second surface of the wall are performed simultaneously.

4. The method according to claim 1, further comprising heating the first glass plate prior to irradiating the first surface.

5. The method according to claim 1, wherein the unsealed portion comprises a pair of unsealed portions positioned on opposite sides of the sealed portion

6. The method according to claim 1, wherein the organic material comprises an organic light emitting diode.

7. The method according to claim 1, wherein the photonic device comprises a photovoltaic device.

8. The method according to claim 1, wherein the photonic device comprises a lighting panel.

9. A method of sealing a glass package comprising:
positioning a first glass plate over a second glass plate, the first glass plate comprising a wall adhered to a surface thereof, the wall comprising a glass sealing material;
irradiating a first surface of the wall with a first laser beam through the first glass plate, the first wall surface adjacent the first glass plate;
irradiating a second surface of the wall with a second laser beam through the second glass plate, the second wall surface adjacent the second glass plate; and
wherein the irradiating the first and second surfaces of the wall couples the first glass plate to the second glass plate, and wherein the second surface comprises a sealed portion and an unsealed portion, and wherein a width of the sealed portion comprises equal to or greater than 80% of the maximum width of the wall.

10. The method according to claim 9, wherein irradiating the first and second wall surfaces is performed sequentially.

11. The method according to claim 9, wherein the irradiating the first and second wall surfaces is performed simultaneously.
